(19) United States
(12) Patent Application Publication
(10) Pub. No.: US 2025/0122621 A1
(43) Pub. Date: Apr. 17, 2025

(54) PROCESS CHAMBER GAS FLOW IMPROVEMENT

(71) Applicant: Applied Materials, Inc., Santa Clara, CA (US)

(72) Inventor: Zhepeng CONG, San Jose, CA (US)

(21) Appl. No.: 18/486,291

(22) Filed: Oct. 13, 2023

(51) Int. Cl. C23C 16/455; C23C 16/44; C23C 16/56; H01L 21/02; H01L 21/3065

(52) U.S. Cl. CPC C23C 16/45561; C23C 16/4408; C23C 16/56; H01L 21/02532; H01L 21/3065

(57) ABSTRACT

A processing system is provided that includes a process chamber. The process chamber includes: a chamber body disposed around a process volume and a substrate support. The processing system further includes a gas supply system coupled to a gas inlet of the process chamber, the gas supply system including: a main gas line connected with the gas inlet of the process chamber. The main gas line includes a first valve configured to open and provide a gas flow path through the main gas line to the process chamber. A first process gas line is connected with the main gas line at a first connection located upstream of the first valve. A second process gas line is connected with the main gas line at a second connection located upstream of the first valve. The main gas line can be separately purged upstream and downstream of the first valve.

### BACKGROUND

### Field

Embodiments of the present disclosure generally relate to equipment and related methods for improving the gas flow to process chambers, such as semiconductor process chambers.

### Description of the Related Art

Process chambers, such as semiconductor process chambers, are often used to perform more than one process on different substrates or more than one process on the same substrate. For example, a deposition process chamber, such as epitaxial deposition chamber, can be used to: (1) deposit a first layer formed of a first material over a substrate during a first time period; and (2) deposit a second layer formed of a second material during a second time period. One or more gases can be supplied to the process chamber during the first time period to deposit the first layer. One or more different gases can be supplied to the process chamber during the second time period to deposit the second layer.

Although processes, such as depositions, can be performed within tight tolerances (e.g., target deposition thicknesses), the dimensions on components (e.g., layers in semiconductor depositions) continue to scale down further reducing the room for error. Hitting process targets, such as deposition thicknesses, can be especially challenging in process chambers that are used to perform more than one process on a substrate, such as alternating depositions. Thus, there is a continuing need to perform processes, such as depositions, within tighter and tighter tolerances, so that process targets can be achieved within intended specifications.

### SUMMARY

Embodiments of the present disclosure generally relate to equipment and related methods for improving the gas flow to process chambers, such as semiconductor process chambers.

In one embodiment, a processing system is provided that includes a process chamber. The process chamber includes: a chamber body disposed around a process volume; a substrate support in the process volume; a gas inlet coupled with the process volume; and an exhaust outlet. The processing system further includes a gas supply system coupled to the gas inlet of the process chamber, the gas supply system including: a main gas line connected with the gas inlet of the process chamber, wherein the main gas line includes a first valve configured to open and provide a gas flow path through the main gas line to the gas inlet of the process chamber; a first process gas line connected with the main gas line at a first connection located upstream of the first valve; a second process gas line connected with the main gas line at a second connection located upstream of the first valve; a first purge gas line connected with the main gas line at a first purge gas connection that is downstream of the first valve; and a second purge gas line connected with the main gas line at a second purge gas connection that is upstream of the first valve.

In another embodiment, a method for processing a substrate is provided comprising: a) positioning a substrate on a substrate support in a process volume of a process chamber; b) supplying a first process gas from a first process gas source to the process volume through a main gas line during a first time period, wherein the main gas line includes a first valve having an inlet side and an outlet side, and the first valve is opened during the first time period; c) depositing a first layer on the substrate with first process gas; d) closing the first valve during a second time period; e) directing a first gas flow of purge gas to the process volume of the process chamber through a first section of the main gas line on the outlet side of the first valve during a second time period; and f) directing a second gas flow of purge gas through a second section of the main gas line on the inlet side of the first valve during a third time period.

In another embodiment, a method for processing a substrate is provided comprising: a) positioning a substrate on a substrate support in a process volume of a process chamber; b) supplying a first process gas from a first process gas source to the process volume through a main gas line during a first time period, wherein the main gas line includes a first valve having an inlet side and an outlet side and the first valve is opened during the first time period; c) performing a first process on the substrate with first process gas during the first time period; and d) directing a first flow of purge gas through a section of the main gas line to waste without directing the first flow of purge gas through the process chamber during a second time period.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a cross-sectional view of a processing system, according to one embodiment.

FIG. 2 is a process flow diagram of a method for processing a substrate in the processing system from FIG. 1, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to equipment and related methods for improving the gas flow to process chambers, such as semiconductor process chambers. The improvements relate to using finer control over the process gases that are supplied to the interior volume of the process chamber. This finer degree of control is achieved by purging a significant portion of the residual process gas remaining in the gas supply line along a path to waste that does not include the interior volume of the process chamber. Directing this residual gas to waste without sending this gas through the interior volume of the process chamber prevents unintended processes from occurring in the process chamber, such as unintended depositions resulting from the residual process gas being directed through the process chamber in conventional processes. In some embodiments, directing the residual gas in the gas lines to waste without sending the residual gas through the process chamber can also be performed more quickly than purging all of the residual gas through the process chamber as the residual gas has less distance to travel before being removed from the gas supply line.

Although the following disclosure mainly describes improvements in equipment and methods for finer control over achieving process targets (e.g., deposition thickness) for depositions performed on substrates in an epitaxial deposition chamber, the benefits of this disclosure can also be applied to other deposition chambers (e.g., chemical vapor deposition (CVD) chambers or plasma enhanced CVD chambers) as well as to process chambers configured to perform different processes, such as etching. More generally, the benefits of this disclosure can apply to any process that supplies different gases to the same process chamber during different time periods.

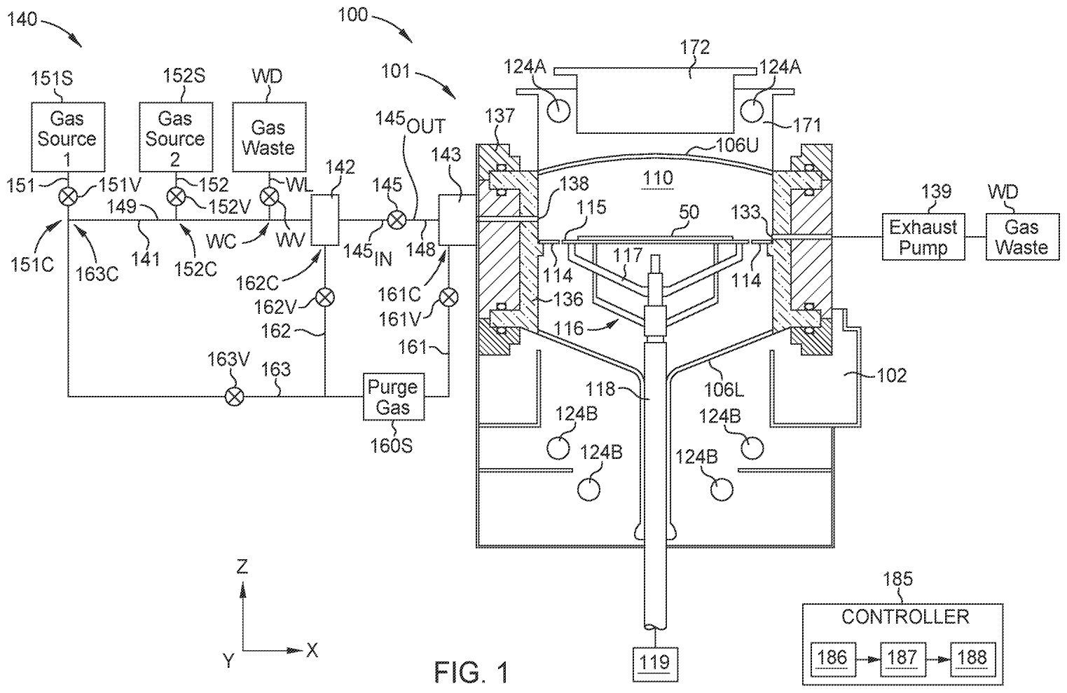

FIG. 1 is a cross-sectional view of a processing system 100, according to one embodiment. The processing system 100 includes a process chamber 101, a gas supply system 140, an exhaust pump 139, and a controller 185. The processing system 100 can be configured to perform epitaxial deposition processes in the process chamber 101 as well as other processes, such as cleaning processes.

The process chamber 101 includes a chamber body 102. In some embodiments, the chamber body 102 can be made of a process resistant material, such as aluminum or stainless steel, for example 316L stainless steel. The chamber body 102 is disposed around structural components of the process chamber 101, such as an upper window 106U, a lower window 106L, an inner liner 136, and an outer liner 137. In one embodiment, the windows 106U, 106L can each be formed of quartz. The liners 136, 137 can be positioned between the windows 106U, 106L and the chamber body 102 to insulate the windows 106U, 106L from the chamber body 102. The windows 106U, 106L and the liners 136, 137 enclose an interior volume 110 (also referred to as process volume) of the process chamber 101. The process chamber 101 can further include a gas inlet 138 extending through the liners 136, 137 to provide a gas flow path into the interior volume 110 from outside of process chamber 101.

The process chamber 101 includes a substrate support assembly 116. The substrate support assembly 116 can include supports 117 and a shaft 118. A susceptor 115 can be positioned on the supports 117. The substrate support assembly 116 can further include an actuator 119 to rotate the shaft 118 and the susceptor 115. A substrate 50 can be positioned on the susceptor 115 during processing, such as during an epitaxial deposition.

Gases can be introduced into the interior volume 110 from the gas supply system 140 during depositions, cleaning, or other processes. These gases can be exhausted from the interior volume 110 through an exhaust outlet 133 by the exhaust pump 139, which directs the exhausted gas to a gas waste dump WD. The process chamber 101 can further include a preheat ring 114 that can be positioned around the susceptor 115.

The process chamber 101 can further include upper lamp modules 124A and lower lamp modules 124B for heating of the substrate 50 and/or the interior volume 110. In one embodiment, the upper lamp modules 124A and the lower lamp modules 124B are infrared (IR) lamps.

The process chamber 101 further includes an outer reflector 171 and an inner reflector 172 positioned over the upper window 106U. The outer reflector 171 can be positioned around the inner reflector 172. In some embodiments one or more upper lamp modules 124A can be positioned inside the outer reflector 171.

The gas supply system 140 includes a main gas line 141, a first process gas line 151, a second process gas line 152, a first purge gas line 161, a second purge gas line 162, a third purge gas line 163, and a waste line WL. The gas supply system 140 further includes a first process gas source 151S, a second process gas source 152S, a purge gas source 160S, and a gas waste dump WD that can be the same as the waste dump connected to the exhaust pump 139. The first process gas source 151S is connected to the first process gas line 151. The second process gas source 152S is connected to the second process gas line 152. The purge gas source 160S is connected to each of the first purge gas line 161, the second purge gas line 162, and the third purge gas line 163. Although only two process gas lines 151, 152 and corresponding gas sources 151S, 152S are shown, other embodiments can include three or more (e.g., ten or more) process gas lines and three or more (e.g., ten or more) process gas sources.

The waste line WL is connected to the gas waste dump WD. The waste line WL includes a waste valve WV that can be opened to provide a gas flow path to send gases to the gas waste dump WD, for example when portions of the main gas line 141 are being purged as described in further detail below. The waste line WL connects to the main gas line 141 at a waste connection WC that is located downstream of the process gas connections 151C, 152C on the inlet side 145_{IN} of the isolation valve 145, which is described in further detail below. In some embodiments (not shown), the waste connection WC can be located upstream of the process gas connections 151C, 152C and the third purge gas line 163 can be omitted.

The main gas line 141 includes a plurality of flow distribution devices 142, a gas injector 143, and an isolation valve 145 (also referred to as first valve) positioned between the plurality of flow distribution devices 142 and the gas injector 143. Process gas(es) can flow through each of these components on the main gas line 141 and into the interior volume 110 of the process chamber 101 when the isolation valve 145 is opened and the corresponding process gas valves are opened. The isolation valve 145 has an inlet 145_{IN} (also referred to as gas inlet side 145_{IN}) and an outlet 145_{OUT} (also referred to as gas outlet side 145_{OUT}). Process gas can flow from the gas inlet 145_{IN}, through the valve 145, and then out the outlet 145_{OUT} as the process flows through the main line 141 towards the process chamber 101. The main gas line 141 includes a first section 148 on the outlet side 145_{OUT} of the isolation valve 145 and a second section 149 on the inlet side 145_{IN} of the isolation valve 145. The first section 148 can be purged separately from the second section 149 as described in further detail below.

In some embodiments, the gas injector 143 is part of the process chamber 101. The gas injector 143 and the gas inlet 138 of the process chamber 101 can extend around the interior volume 110 of the process chamber 101, so that gas can be introduced into the interior volume 110 across a wider area and flow over all of the top surface of the substrate 50. In one embodiment, the gas injector 143 and the gas inlet 138 extend from about 15 degrees to about 120 degrees around the interior volume 110 of the process chamber 101. Although one isolation valve 145 is shown, some embodiments can include two or more isolation valves, for example at different angular locations around the process chamber 101 to control the flow of process gas to different portions of the gas injector 143 and to different portions of the interior volume 110. Furthermore, the flow distribution devices 142 can include other components for splitting the flow of the main line 141 into two or three or more different supply lines that can be more evenly distributed to the gas injector 143.

The first process gas line 151 includes a first process gas valve 151V. One or more process gases from the first process gas source 151S can flow into the main gas line 141 when the first process gas valve 151V is opened. The first process gas line 151 can be connected to the main gas line 141 at a first connection 151C located upstream of the isolation valve 145 on the gas inlet side 145_{IN} of the isolation valve 145. Used herein, upstream and downstream refer to relative locations along the gas flow path for process gases into the process chamber 101, for example with the interior volume 110 of the process chamber 101 being downstream of the isolation valve 145 and the process gas connections (e.g., the first connection 151C) being upstream of the isolation valve 145.

The second process gas line 152 includes a second process gas valve 152V. One or more process gases from the second process gas source 152S can flow into the main gas line 141 when the second process gas valve 152V is opened. At least one of the one or more process gases from the second gas source 152S is different than at least one of the one or more gases from the first process gas source 151S. The second process gas line 152 can be connected to the main gas line 141 at a second connection 152C located upstream of the isolation valve 145 on the gas inlet side 145_{IN} of the isolation valve 145.

The first purge gas line 161 includes a first purge gas valve 161V. One or more purge gases (e.g., H₂) from the purge gas source 160S can flow along a gas flow path into the gas injector 143 on the main gas line 141 and then into the interior volume 110 of the process chamber 101 when the first purge gas valve 161V is opened and the isolation valve 145 is closed. The first purge gas line 161 can be connected to the gas injector 143 of the main gas line 141 at a first purge gas connection 161C located downstream of the isolation valve 145 on the gas outlet side 145_{OUT} of the isolation valve 145. In some embodiments, the first purge gas connection 161C is located within a small distance (e.g., from about 0.5 inches to about 12 inches) of the outlet 145_{OUT} of the isolation valve 145.

The second purge gas line 162 includes a second purge gas valve 162V. One or more purge gases (e.g., H₂) from the purge gas source 160S can flow along a gas flow path into a portion of the main gas line 141 that includes the flow distribution devices 142 with the gas flow path continuing to the waste line WL and finally to the gas waste dump WD when (1) the second purge gas valve 162V and the waste valve W are opened, and (2) the isolation valve 145 is closed.

The second purge gas line 162 can be connected to a portion of the main gas line 141 that includes the flow distribution devices 142 at a second purge gas connection 162C located upstream of the isolation valve 145 on the gas inlet side 145_{IN} of the isolation valve 145. In some embodiments, the second purge gas connection 162C is located within a small distance (e.g., from about 0.5 inches to about 12 inches) of the inlet 145_{IN} of the isolation valve 145. The purge gas from the second purge gas line 162 can be used to purge the portion of the main gas line 141 that is downstream of the waste line WL and upstream of the isolation valve 145. This portion of the main gas line 141 can include a relatively large internal volume, for example an interior volume that is at least 50% or at least two times greater than the interior volume of the main gas line 141 that is downstream of the isolation valve 145.

Using the second purge gas line 162 to purge this portion of the main line that is upstream of the isolation valve 145 substantially reduces the amount of process gases that are directed through the interior volume 110 of the process chamber 101 during a purging process or when the process gas source is switched, for example from the first process gas source 151S to the second process gas source 152S. Reducing the amount of process gases that are introduced into the interior volume 110 of the process chamber during purging processes or when process gases are switched enables finer control over the processes (e.g., depositions) performed on substrates in the interior volume 110 of the process chamber 101. For example, layers can be deposited with thicknesses closer a specified target thickness.

The third purge gas line 163 includes a third purge gas valve 163V. One or more purge gases (e.g., H₂) from the purge gas source 160S can flow along a gas flow path into a portion of the main gas line 141 that is upstream of the waste line WL with the gas flow path continuing into the waste line WL and finally to the gas waste dump WD when (1) the third purge gas valve 163V and the waste valve W are opened, and (2) the isolation valve 145 is closed. The third purge gas line 163 can be connected to a portion of the main gas line 141 at a third purge gas connection 163C that is a same location as the first connection 151C where the first process gas line 151 connects to the main gas line 141. The third purge gas connection 163C is upstream of the waste line WL, upstream of the second connection 152C, and at the same location as the first connection 151C, so that substantially all of the process gases downstream of the valves 151V, 152V can be purged when the third purge gas valve 163V and the waste valve WV are opened and the isolation valve 145 is closed. In some embodiments, the third purge gas connection 163C is also located upstream of the first connection 151C. Using the third purge gas line 163 to purge the main gas line 141 in this manner also reduces the amount of process gases that go through the process chamber 101 during a purging process because the isolation valve 145 is closed and the gases are sent to the gas waste dump WD instead of being sent through the interior volume 110 of the process chamber 101.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as epitaxial deposition processes and purging processes. During execution of these programs, the controller 185 can communicate to I/O devices through the I/O circuits 188. For example, during execution of these programs and communication through the I/O circuits 188, the controller 185 can control outputs, such as the position of valves to send process gases to the interior volume 110 of the process chamber 101 or to perform purging processes. The memory 186 can further include various operational settings used to control the processing system 100. For example, the settings can include durations for how long the different valves remain open or closed during different depositions and purging processes.

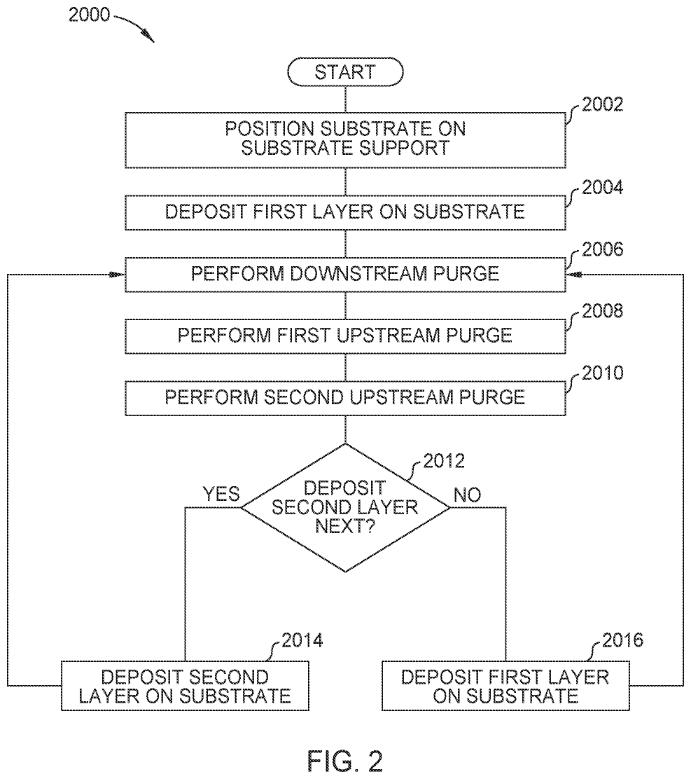

FIG. 2 is a process flow diagram of a method 2000 for processing a substrate 50 in the processing system 100 from FIG. 1, according to one embodiment. The method 2000 is described in reference to FIGS. 1 and 2. The method 2000 can be executed by the controller 185. The method 2000 is an exemplary method of depositing alternating layers over a substrate in which one or more gases are supplied to the interior volume 110 of the process chamber 101 to deposit a first layer (e.g., a layer including silicon and germanium), and then one or more different gases are supplied to the interior volume 110 of the process chamber 101 to deposit a second layer (e.g., a layer including silicon without germanium). The alternating depositions can be repeated any number of times (e.g., thirty times). The interior volume 110 of the process chamber 101 and the gas supply lines (e.g., main gas line 141) are quickly purged between each deposition of the alternating depositions. The gas supply lines are primarily purged by directing the residual gas in the supply lines to waste without sending the residual gas in the supply lines through the interior volume 110 of the process chamber 101.

Directing this residual gas to waste without sending this gas through the interior volume 110 of the process chamber 101 prevents unintended processes from occurring in the process chamber 101, such as unintended depositions that can prevent target deposition thicknesses from being achieved. In some embodiments, directing the residual gas in the gas lines to waste without sending the residual gas through the interior volume 110 process chamber 101 can also be performed more quickly than purging the residual gas through the process chamber 101 as the residual gas has less distance to travel before being removed from the gas supply line. Although the method 2000 is described in reference to performing alternating depositions, the benefits of the method can more generally be applied to any process (e.g., etching, cleaning, etc.) in which different gases are supplied to a process chamber during different time periods.

The method begins at block 2002. At block 2002, a substrate is positioned on the susceptor 115 in the interior volume 110 of the process chamber 101.

At block 2004, one or more process gases from the first process gas source 151S are introduced into the interior volume 110 of the process chamber 101 to deposit a first layer formed of a first material on the substrate 50 during a first time period. The first process gas valve 151V and the isolation valve 145 are opened during the first time period to supply the one or more gases from the first process gas source 151S to the interior volume 110 of the process chamber 101. Valves shown in FIG. 1 and not mentioned during a particular block of the method 2000 can be assumed to be closed during the execution of that block of the method 2000.

At block 2006, a downstream purging process is performed during a second time period (may also be referred to as third time period) after the process performed during the first time period is completed. During the second time period, the first process gas valve 151V and the isolation valve 145 are closed, and the first purge gas valve 161V is opened. During the downstream purging process, a first gas flow of purge gas (e.g., hydrogen (H₂)) can be directed (1) from the purge gas source 160S through the first purge gas line 161 (2) into the first section 148 of the main gas line 141 and through the gas injector 143 on the outlet side 145_{OUT} of the isolation valve 145, (3) through the interior volume 110 of the process chamber 101, and (4) to the exhaust pump 139 and gas waste dump WD. This downstream purging process removes process gases downstream of the isolation valve 145 on the outlet side 145_{OUT} of the isolation valve 145 including any residual process gases remaining in the interior volume 110 of the process chamber 101.

At block 2008, a first upstream purging process is performed during a third time period (may also be referred to as second time period). In some embodiments, the first upstream purging process is performed simultaneously with the downstream purging process of block 2006 or there is at least some overlapping of the second time period with the third time period. During the first upstream purging process, the isolation valve 145 remains closed and the second purge gas valve 162V and the waste valve W are opened. During this first upstream purging process, a second gas flow of purge gas (e.g., H₂) can be directed (1) from the purge gas source 160S through the second purge gas line 162, (2) into the second section 149 of the main gas line 141, and (3) through the waste line WL to the gas waste dump WD.

At block 2010, a second upstream purging process is performed during a fourth time period. In some embodiments, the second upstream purging process is performed simultaneously with the execution of blocks 2006, 2008 or there is at least some overlapping of the fourth time period with the second time period and/or third time period. Simultaneous performance of blocks 2006, 2008, and 2010 can increase efficiency leading to higher rates of production for the process chamber. In one embodiment, the second, third, and fourth time periods each start simultaneously. Furthermore, in some embodiments, the upstream purging operations described as occurring during the third and fourth time periods can occur before the downstream purging described as occurring during the second time period.

During the second upstream purging process, the isolation valve 145 remains closed and the third purge gas valve 163V and the waste valve WV are opened. During this second upstream purging process, a third gas flow of purge gas (e.g., H₂) can be directed (1) from the purge gas source 160S through the third purge gas line 163 to the third purge gas connection 163C, (2) through the portion of the main gas line 141 between third purge gas connection 163C and the waste line connection WC, and (3) through the waste line WL to the gas waste dump WD.

At block 2012, a determination is made by the controller 185 whether to deposit the second layer next or the first layer next. If the controller 185 determines to deposit the second layer next, then the method 2000 proceeds to block 2014. Alternatively, if the controller 185 determines to deposit the first layer next, then the method 2000 proceeds to block 2016. In one embodiment, the controller 185 determines to deposit the second layer next if the first layer was the most recently deposited layer, and the controller 185 determines to deposit the first layer next if the second layer was the most recently deposited layer, so that the first layer and second layer can be deposited in an alternating sequence.

At block 2014, one or more process gases from the second process gas source 152S are introduced into the interior volume 110 to deposit a second layer of a second material on the substrate 50 during a fifth time period. The second material for the second layer is different than the first material of the first layer. The second process gas valve 152V and the isolation valve 145 are opened during the fifth time period to supply the one or more gases from the second process gas source 152S to the interior volume 110 of the process chamber 101. Alternatively, in one embodiment, the first process performed during blocks 2004 and 2016 is a deposition, and the second process performed during block 2014 is an etching process. In another embodiment, three processes are performed in the process volume including: (1) a deposition of silicon (Si); (2) a deposition of silicon germanium (SiGe); and (3) an etching of the silicon germanium layer, for example with hydrogen chloride (HCl) with the downstream purging (see block 2006) and the upstream purging (see blocks 2008 and 2010) being performed between each of the three processes.

At block 2016, the operations described in reference to block 2004 are repeated to deposit another first layer over the substrate 50. After the execution of either block 2014 or block 2016, the method 2000 performs another purge of the process chamber 101 and gas lines by repeating blocks 2006-2010. After repeating blocks 2006-2010, the method 2000 then proceeds to block 2012 to make the determination to deposit the first layer next at block 2016 or the second layer next at block 2014. Blocks 2006-2016 can then be repeated any number of times to deposit the alternating pattern of the first layer and the second layer.

While the foregoing is directed to embodiments of the present disclosure, other and further embodiments of the disclosure may be devised without departing from the basic scope thereof.

What is claimed is:

1. A processing system comprising:
a process chamber comprising:
a chamber body disposed around a process volume;
a substrate support in the process volume;
a gas inlet coupled with the process volume; and
an exhaust outlet; and
a gas supply system coupled to the gas inlet of the process chamber, the gas supply system comprising:
a main gas line connected with the gas inlet of the process chamber, wherein the main gas line includes a first valve configured to open and provide a gas flow path through the main gas line to the gas inlet of the process chamber;
a first process gas line connected with the main gas line at a first connection located upstream of the first valve;
a second process gas line connected with the main gas line at a second connection located upstream of the first valve;
a first purge gas line connected with the main gas line at a first purge gas connection that is downstream of the first valve; and
a second purge gas line connected with the main gas line at a second purge gas connection that is upstream of the first valve.

2. The processing system of claim 1, further comprising a waste line connected to the main gas line at a first waste connection that is located upstream of the first valve.

3. The processing system of claim 2, wherein the waste line includes a waste valve configured to open and provide a gas flow path through the waste line to a gas dump.

4. The processing system of claim 1, wherein the first purge gas line includes a first purge gas valve configured to open to provide a gas flow path from a purge gas source through the first purge gas line and to the gas inlet of the process chamber.

5. The processing system of claim 2, wherein the second purge gas line includes a second purge gas valve configured to open to provide a gas flow path from a purge gas source through the second purge gas line, through the main gas line, and to the waste line.

6. The processing system of claim 2, further comprising a third purge gas line connected with the main gas line at a third purge gas connection that is upstream of the second purge gas connection.

7. The processing system of claim 6, wherein the second purge gas line includes a third purge gas valve configured to open to provide a gas flow path from a purge gas source through the third purge gas line, through the main gas line, and to the waste line.

8. The processing system of claim 6, wherein the third purge connection is upstream of the first connection for the first process gas line and the second connection for the second process gas line.

9. A method for processing a substrate comprising:
a) positioning a substrate on a substrate support in a process volume of a process chamber;
b) supplying a first process gas from a first process gas source to the process volume through a main gas line during a first time period, wherein the main gas line includes a first valve having an inlet side and an outlet side, and the first valve is opened during the first time period;
c) depositing a first layer on the substrate with first process gas;
d) closing the first valve during a second time period;
e) directing a first gas flow of purge gas to the process volume of the process chamber through a first section of the main gas line on the outlet side of the first valve during a second time period; and
f) directing a second gas flow of purge gas through a second section of the main gas line on the inlet side of the first valve during a third time period.

10. The method of claim 9, further comprising:
opening the first valve;
supplying a second process gas from a second process gas source to the process volume through the main gas line during a fourth time period; and
depositing a second layer on the substrate with second process gas.

11. The method of claim 10, further comprising repeating operations d), e), and f) after depositing the second layer on the substrate.

12. The method of claim 9, wherein the second time period and the third time period overlap.

13. The method of claim 9, wherein the second time period and the third time period start simultaneously.

14. A method for processing a substrate comprising:
a) positioning a substrate on a substrate support in a process volume of a process chamber;
b) supplying a first process gas from a first process gas source to the process volume through a main gas line during a first time period, wherein the main gas line includes a first valve having an inlet side and an outlet side and the first valve is opened during the first time period;
c) performing a first process on the substrate with first process gas during the first time period; and
d) directing a first flow of purge gas through a section of the main gas line to waste without directing the first flow of purge gas through the process chamber during a second time period.

15. The method of claim 14, further comprising:
e) directing a second flow of purge gas through another section of the main gas line to the process volume of the process chamber during a third time period.

16. The method of claim 15, wherein the second time period and the third time period overlap.

17. The method of claim 15, wherein the second time period and the third time period start simultaneously.

18. The method of claim 15, further comprising:
supplying a second process gas from a second process gas source to the process volume through the main gas line during a fourth time period; and
performing a second process on the substrate with the second process gas during the fourth time period.

19. The method of claim 18, further comprising repeating operations d) and e) after performing the second process on the substrate.

20. The method of claim 18, wherein the first process is a deposition, and the second process is an etch.
